(19) United States
(12) Patent Application Publication
(10) Pub. No.: US 2010/0307590 A1
(43) Pub. Date: Dec. 9, 2010

(54) PHOTOELECTRIC CONVERSION DEVICE

(75) Inventors: Shunpei YAMAZAKI, Tokyo (JP); Kazuo NISHI, Fujisawa (JP)

Correspondence Address: Robinson Intellectual Property Law Office, P.C., 3975 Fair Ridge Drive, Suite 20 North, Fairfax, VA, 22033, US

(73) Assignee: Semiconductor Energy Laboratory Co., Ltd., Kanagawa-ken (JP)

(21) Appl. No.: 12/792,175

(22) Filed: Jun. 2, 2010

(30) Foreign Application Priority Data
Jun. 5, 2009 (JP) 2009-136740

(51) Int. Cl. H01L 31/00

(52) U.S. Cl. 136/261

(57) ABSTRACT

The present invention provides a technique in which a cheap zinc oxide material can be used as a light-transmitting conductive film of a photoelectric conversion device. The present invention is a photoelectric conversion device including, between a first electrode and a second electrode, at least one unit cell in which a first impurity semiconductor layer having one conductivity type, a semiconductor layer, and a second impurity semiconductor layer having a conductivity type opposite to the first impurity semiconductor layer are sequentially stacked and a semiconductor junction is included. The first electrode or the second electrode includes conductive oxynitride containing zinc and aluminum. In the conductive oxynitride containing zinc and aluminum: the relative proportion of the zinc is less than or equal to 47 at. % and higher than that of the aluminum; and the relative proportion of the aluminum is higher than that of nitrogen.

### BACKGROUND OF THE INVENTION

1. Field of the Invention

One embodiment of the present invention relates to a photoelectric conversion device utilizing a photovoltaic effect of a semiconductor. One embodiment to be disclosed includes a photoelectric conversion device using a light-transmitting conductive film.

2. Description of the Related Art

In part of a structure of a photoelectric conversion device which is formed using a semiconductor thin film, a light-transmitting conductive film is used. For example, a light-transmitting conductive film is used as: an electrode on a light incidence side of a photoelectric conversion device; an intermediate conductive layer provided between an upper photoelectric conversion cell and a lower photoelectric conversion cell of a tandem photoelectric conversion device; or a conductive layer between a reflective electrode provided on a rear side and a semiconductor layer of a photoelectric conversion device (for example, see Patent Documents 1 and 2).

As a light-transmitting conductive film used in a photoelectric conversion device, a tin oxide film or a film of a compound of indium oxide and tin oxide (In₂O₃—SnO₂, which is hereinafter abbreviated to ITO) which is formed using a target obtained by adding tin oxide to indium oxide and performing sintering is conventionally used.

ITO has a lower resistivity and a higher degree of transparency in the visible light range than any other material for a light-transmitting conductive film. At the same time, though industrially used, indium, which is a main material of ITO, has intrinsic problems: indium is rare metal and thus expensive and is produced only in a limited number of indium-producing countries.

Tin oxide has a higher resistivity than ITO and needs to be formed to a large thickness. Moreover, in order to make a tin oxide film suitable for a photoelectric conversion device, a substrate temperature needs to be high (for example, see Patent Document 3).

Zinc oxide is another known material for a light-transmitting conductive film, a zinc oxide film is known. Zinc oxide is said to be inferior to ITO in transparency and conductivity but is much cheaper than ITO. For example, the cost of a target obtained by sintering zinc oxide is about two thirds to half of that of a target obtained by sintering ITO. In addition, a method for forming a light-transmitting conductive oxide is known in which a slight amount of aluminum which functions as a donor is contained in zinc oxide in order to improve the conductivity of zinc oxide (see Patent Document 4).

### REFERENCES

### Patent Documents

[Patent Document 1] Japanese Published Patent Application No. 2001-028452
[Patent Document 2] Japanese Published Patent Application No. H02-073672
[Patent Document 3] Japanese Published Patent Application No. S63-313874
[Patent Document 4] Japanese Published Patent Application No. 2007-238375

### SUMMARY OF THE INVENTION

However, a conventional zinc oxide film has low chemical resistance and thus is soluble in an alkaline solution; and it has low moisture resistance which increases resistivity. Therefore, even if the zinc oxide film is used as a light-transmitting conductive film of a photoelectric conversion device, properties of the device cannot be improved or stabilized.

An object of one embodiment of the present invention is to provide a technique in which a cheap zinc oxide material can be used as a light-transmitting conductive film of a photoelectric conversion device.

One embodiment of the present invention is a photoelectric conversion device including, between a first electrode and a second electrode, at least one unit cell in which a first impurity semiconductor layer having one conductivity type, a semiconductor layer, and a second impurity semiconductor layer having a conductivity type opposite to the first impurity semiconductor layer are sequentially stacked to form a semiconductor junction is included. The first electrode or the second electrode includes conductive oxynitride containing zinc and aluminum.

One embodiment of the present invention is a photoelectric conversion device including: a first electrode; a first unit cell formed over the first electrode; an intermediate conductive layer formed over the first unit cell; a second unit cell formed over the intermediate conductive layer; and a second electrode formed over the second unit cell. In the first unit cell, a first impurity semiconductor layer having one conductivity type, a first semiconductor layer, and a second impurity semiconductor layer having a conductivity type opposite to the conductivity of the first impurity semiconductor layer are sequentially stacked to form a semiconductor junction. In the second unit cell, a third impurity semiconductor layer having one conductivity type, a second semiconductor layer, and a fourth impurity semiconductor layer having a conductivity type opposite to the conductivity of the third impurity semiconductor layer are sequentially stacked to form a semiconductor junction. The first electrode, the second electrode, or the intermediate conductive layer includes conductive oxynitride containing zinc and aluminum.

Note that in the conductive oxynitride containing zinc and aluminum: the relative proportion of the zinc is less than or equal to 47 at. % and higher than the relative proportion of the aluminum; the relative proportion of the aluminum is higher than the relative proportion of nitrogen; and the nitrogen concentration measured by secondary ion mass spectrometry is greater than or equal to 5.0×10²⁰ atoms/cm³. In the conductive oxynitride containing zinc and aluminum, alternatively, the relative proportion of the zinc is less than or equal to 47 at. % and higher than the relative proportion of the aluminum; the relative proportion of the aluminum is higher than the relative proportion of the nitrogen; and the aluminum is included at 1.0 at. % to 8.0 at. % and the nitrogen is included at 0.5 at. % to 4.0 at. %.

In this specification, a nitrogen concentration, an oxygen concentration, and a carbon concentration are peak concentrations which are measured by secondary ion mass spectrometry (SIMS). The unit of a relative proportion of conductive oxynitride containing zinc and aluminum is at. % and the relative proportion is evaluated by analysis using an electron probe X-ray microanalyzer (EPMA).

The term “non-single-crystal semiconductor” in this specification includes a substantially intrinsic semiconductor in its category, and specifically, refers to a non-single-crystal semiconductor which has an impurity imparting p-type conductivity (typically boron) or n-type conductivity (typically phosphorus) at a concentration of less than 1×10¹⁸/cm³ and which has photoconductivity of 100 times or more of dark conductivity. Note that there is a case where a non-single-crystal semiconductor has low n-type electrical conductivity when an impurity element for controlling valence electrons is not added intentionally; therefore, an impurity imparting p-type conductivity (typically boron) may be added during or after formation of the non-single-crystal semiconductor film. In such a case, the concentration of a p-type impurity included in a non-single-crystal semiconductor is approximately 1×10¹⁴/cm³ to 6×10¹⁶/cm³.

The term “photoelectric conversion layer” in this specification includes in its category a semiconductor layer by which a photoelectric (internal photoelectric) effect is achieved and moreover an impurity semiconductor layer which is joined to form an internal electric field or a semiconductor junction. In other words, the photoelectric conversion layer in this specification refers to a semiconductor layer having a junction typified by a p-i-n junction or the like.

The term “p-i-n junction” in this specification includes a junction in which a p-type semiconductor layer, an i-type semiconductor layer, and an n-type semiconductor layer are sequentially stacked from the light incidence side and a junction in which an n-type semiconductor layer, an i-type semiconductor layer, and a p-type semiconductor layer are sequentially stacked from the light incidence side.

Note that the ordinal numbers such as “first”, “second”, and “third” in this specification are used for convenience to distinguish elements. Therefore, these ordinal numbers do not limit the number, the arrangement, and the order of steps.

A light-transmitting conductive film having a favorable light-transmitting property and conductivity can be formed at low cost, which realizes reduction in the cost of a photoelectric conversion device.

Since the resistivity of the light-transmitting conductive film can be reduced, photocurrent extraction efficiency can be improved.

### BRIEF DESCRIPTION OF THE DRAWINGS

In the accompanying drawings:

FIG. 1 is a schematic cross-sectional view illustrating a photoelectric conversion device of one embodiment of the present invention;

FIG. 2 is a schematic cross-sectional view illustrating a plasma CVD apparatus which is applicable to manufacture of a photoelectric conversion device of one embodiment of the present invention;

FIG. 3 is a schematic plan view illustrating a multi-chamber plasma CVD apparatus which is applicable to manufacture of a photoelectric conversion device of one embodiment of the present invention;

FIG. 4 is a schematic cross-sectional view illustrating a photoelectric conversion device of one embodiment of the present invention;

FIGS. 5A to 5C are cross-sectional views illustrating a manufacturing method of a photoelectric conversion device module of one embodiment of the present invention; and

FIG. 6 is a cross-sectional view illustrating the manufacturing method of the photoelectric conversion device module of one embodiment of the present invention.

### DETAILED DESCRIPTION OF THE INVENTION

Embodiments of the present invention will be described with reference to the drawings. However, the present invention is not limited to the following description, and it is easily understood by those skilled in the art that modes and details can be variously changed without departing from the scope and the spirit of the present invention. Therefore, the present invention should not be limited to the description of the embodiments below. Note that in the structures of the present invention described below, the reference numerals indicating the same are used in common in the drawings.

### Embodiment 1

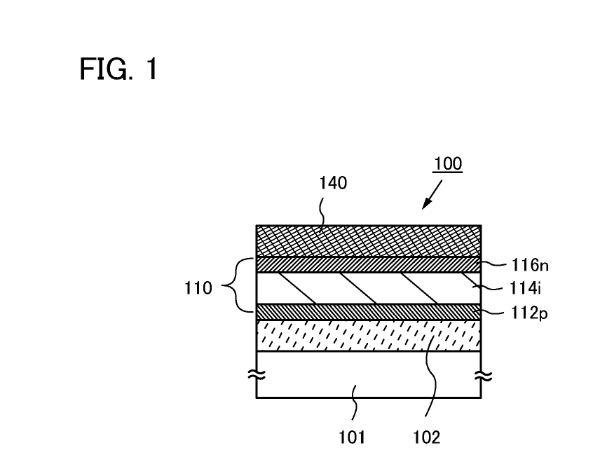

An example of a schematic cross-sectional view of a photoelectric conversion device 100 of this embodiment is illustrated in FIG. 1.

The photoelectric conversion device 100 illustrated in FIG. 1 has a structure in which a unit cell 110 is interposed between a first electrode 102 and a second electrode 140 which are provided over a substrate 101. In the unit cell 110, a semiconductor layer 114i is provided between a first impurity semiconductor layer 112p and a second impurity semiconductor layer 116n, and the unit cell 110 includes at least one semiconductor junction. As the semiconductor junction, a p-i-n junction is typically given.

In this embodiment, since light is incident from the substrate 101 side, a light-transmitting electrode is formed as the first electrode 102. A film of conductive oxynitride containing zinc (Zn), aluminum (Al), nitrogen (N), and oxygen (O) is used as the first electrode 102 in this embodiment. Such a film of conductive oxynitride is called “ZnOAlN”, “AZON”, or conductive oxynitride containing zinc and aluminum. Note that “ZnOAlN” or “AZON” does not indicate the composition ratios between zinc (Zn), aluminum (Al), nitrogen (N) and oxygen (O) which are contained in ZnOAlN or AZON.

In the conductive oxynitride containing zinc and aluminum in this embodiment, the relative proportion of the zinc is typically less than or equal to 47 at. % and is higher than the relative proportion (at. %) of the aluminum. Further, the relative proportion (at. %) of the aluminum is higher than that of nitrogen. The nitrogen concentration measured by SIMS is greater than or equal to 5.0×10²⁰ atoms/cm³ in the conductive oxynitride containing zinc and aluminum. It is preferable that the conductive oxynitride containing zinc and aluminum have at least a polycrystalline structure.

Here, the carrier concentration of the conductive oxynitride containing zinc and aluminum is preferably 1.0×10²⁰/cm³ to 2.0×10²¹/cm³, or more preferably greater than or equal to 2.2×10²⁰/cm³ and less than 4.2×10²⁰/cm³. The mobility of the conductive oxynitride containing zinc and aluminum is preferably 4.0 cm²/V·sec to 60 cm²/V·sec, or more preferably greater than or equal to 4.7 cm²/V·sec and less than 36.0 cm²/V·sec. The resistivity of the conductive oxynitride containing zinc and aluminum is preferably 1.0×10⁻⁴ Ω·cm to 1.0×10⁻² Ω·cm, or more preferably greater than 4.1×10⁻⁴ Ω·cm and less than or equal to 6.1×10⁻³ Ω·cm.

Further, when the conductive oxynitride containing zinc and aluminum is formed to a thickness of about 100 nm, its transmittance of blue light having a wavelength of 470 nm is preferably greater than or equal to 0.70 or more preferably greater than or equal to 0.75. When the conductive oxynitride containing zinc and aluminum is formed to a thickness of about 100 nm, its transmittance of green light having a wavelength of 530 nm is preferably greater than or equal to 0.70 or more preferably greater than or equal to 0.75. When the conductive oxynitride containing zinc and aluminum is formed to a thickness of about 100 nm, its transmittance of red light having a wavelength of 680 nm is preferably greater than or equal to 0.70 or more preferably greater than or equal to 0.75. Note that the conductive oxynitride containing zinc and aluminum satisfies at least one of the above conditions.

In the conductive oxynitride containing zinc and aluminum, the relative proportion of the zinc (at. %) is less than or equal to 47 at. %, which is higher than the relative proportion (at. %) of the aluminum. Further, the relative proportion (at. %) of the aluminum is higher than that of the nitrogen. The aluminum is preferably contained in the conductive oxynitride containing zinc and aluminum in a range of 1.0 at. % to 8.0 at. %; and the nitrogen, in a range of 0.5 at. % to 4.0 at. %.

The conductive oxynitride containing zinc and aluminum can be manufactured so as to have low resistivity by having the above relative proportions. The unit of a relative proportion of the conductive oxynitride containing zinc and aluminum is at. % and evaluation is carried out by analysis using an electron beam microanalyzer.

The conductive oxynitride containing zinc and aluminum has at least a polycrystalline structure. Note that the crystal state is evaluated by X-ray diffraction (XRD) analysis.

Note that a light-transmitting electrode may be formed using a light-transmitting conductive material such as indium oxide, an indium tin oxide (ITO) alloy, or zinc oxide between the first electrode 102 and the substrate 101.

The semiconductor layer 114i is formed using a single crystal semiconductor or a non-single-crystal semiconductor.

As a non-single-crystal semiconductor layer which can be used for the semiconductor layer 114i, an amorphous semiconductor, a micro-crystalline semiconductor, and a polycrystalline semiconductor can be given. As typical examples of an amorphous semiconductor, amorphous silicon, amorphous silicon germanium, and the like can be given. As examples of a microcrystalline semiconductor, microcrystalline silicon, microcrystalline silicon germanium, and the like can be given. As a polycrystalline semiconductor, polysilicon, polysilicon germanium, and the like can be typically given.

The band gap of an amorphous semiconductor (typically amorphous silicon) is 1.6 eV to 1.8 eV and that of a polycrystalline semiconductor (typically polysilicon) is approximately 1.1 eV to 1.4 eV.

The bad gap of a non-single-crystal semiconductor is larger than that of a single crystal semiconductor. Therefore, power can be generated from light in a long wavelength range by the single crystal semiconductor, and also from light in a short wavelength range by the non-single-crystal semiconductor. Since solar light has a wide wavelength band, power generation can be conducted efficiently by employing the structure of this embodiment using the non-single-crystal semiconductor.

As the non-single-crystal semiconductor, a semiconductor in which crystals are dispersed in an amorphous structure may be used. The crystals may be grown so as to continuously penetrate between a pair of impurity semiconductor layers bonded to form an internal electric field, i.e., between a p-type semiconductor layer and an n-type semiconductor layer.

The crystals dispersed in the amorphous structure preferably have a needle-like shape. Here, the needle-like shape includes a conical shape, a pyramidal shape and a pillar-like shape. Specifically, circular conical shape, circular pillar-like shape, a cylindrical shape and a prismatic columnar shape are given. As the pyramidal shape, a triangular pyramidal shape, a quadrangular pyramidal shape, a hexagonal pyramidal shape, and the like are given. As the prismatic columnar shape, a triangular prism, a quadrangular prism, a hexagonal prism, and the like are given. Alternatively, another polygonal pyramidal shape or another prism can be used. Further alternatively, an almost conical or pyramidal shape in which the apex is made to be a plane or an almost cylindrical or prismatic columnar shape with a sharpened end may be used. In the case of a polygonal pyramidal shape or a polygonal prism shape, each side may be equal to or different from each other in length.

The crystals dispersed in the amorphous structure include a crystalline semiconductor such as a microcrystalline semiconductor, a polycrystalline semiconductor, or a single crystal semiconductor, and typically include polysilicon or polysilicon germanium. The amorphous structure includes an amorphous semiconductor, typically amorphous silicon or amorphous silicon germanium. An amorphous semiconductor typified by amorphous silicon or amorphous silicon germanium is a direct transition type and has a high light absorption coefficient. Therefore, in the non-single-crystal semiconductor layer including the crystals in the amorphous structure, photogenerated carriers are produced more easily in the amorphous structure rather than in the crystals.

Moreover, while the amorphous structure including amorphous silicon has a band gap of 1.6 eV to 1.8 eV, a crystal including polysilicon has a band gap of about 1.1 eV to 1.4 eV. Because of such a relationship, the photogenerated carriers produced in the non-single-crystal semiconductor including the crystals in the amorphous structure diffuse or drift into the crystals dispersed in the amorphous structure. The crystals dispersed in the amorphous structure serve as a conduction path (carrier path) of the photogenerated carriers.

With this structure, since the photogenerated carriers flow more easily through the crystals dispersed in the amorphous structure even if photoinduced defects are generated, the probability that photogenerated carriers will be trapped by a defect level of the non-single-crystal semiconductor layer is decreased. Further, when the crystals dispersed in the amorphous structure are formed penetrating between a p-type semiconductor layer and an n-type semiconductor layer, the probability that both electrons and holes, which are photogenerated carriers, will be trapped by a defect level is decreased, which makes it easy for the photogenerated carriers to flow. Accordingly, change of characteristics due to light deterioration which has been a problem can be reduced.

As a single crystal semiconductor which can be used for the semiconductor layer 114i, a sliced single crystal semiconductor substrate may be used. Typically, single crystal silicon sliced off from a single crystal silicon substrate can be used. Since a single crystal semiconductor typified by single crystal silicon has no crystal grain boundaries, the conversion efficiency thereof is higher than that of a polycrystalline, microcrystalline, or amorphous semiconductor. Therefore, an excellent photoelectric conversion characteristic can be obtained.

The bad gap of a single crystal semiconductor (a typical example of which is single crystal silicon) is 1.1 eV.

Either the first impurity semiconductor layer 112p or the second impurity semiconductor layer 116n is formed using a p-type semiconductor layer, and the other is formed using an n-type semiconductor layer. In this embodiment, a structure in which light is incident from the substrate 101 side is described; therefore, a p-type semiconductor layer is formed as the first impurity semiconductor layer 112p and an n-type semiconductor layer is formed as the second impurity semiconductor layer 116n.

Note that the first impurity semiconductor layer 112p and the second impurity semiconductor layer 116n are formed using an amorphous semiconductor (typically amorphous silicon, amorphous silicon carbide or the like), a microcrystalline semiconductor (typically microcrystalline silicon or the like), a polycrystalline semiconductor (polysilicon) or a single crystal semiconductor (single crystal silicon).

Note that it is not necessary to provide the substrate 101 when the first impurity semiconductor layer 112p, the semiconductor layer 114i, and the second impurity semiconductor layer 116n are formed using a single crystal semiconductor.

As the second electrode 140, a reflective electrode is formed using a conductive material such as aluminum, silver, titanium, tantalum, or copper. Note that projections and depressions may be formed on a surface of the second electrode 140. The projections and depressions on the light incidence side can serve as a surface texture, which can improve the light absorptance and realize improvement of photoelectric conversion efficiency.

Note that between the second electrode and the second impurity semiconductor layer 116n, a light-transmitting conductive material such as conductive oxynitride containing zinc and aluminum, indium oxide, an indium tin oxide (ITO) alloy or zinc oxide, which are given also for the first electrode 102, may be provided.

The first electrode is a light-transmitting electrode because light is incident from the substrate 101 side in this embodiment; however, in a case where light is incident from the second electrode 140 side, any of the materials given for the second electrode 140 can be used for the first electrode 102 as appropriate and any of the materials given for the first electrode 102 can be used for the second electrode 140 as appropriate.

As the substrate 101, a substrate with an insulating surface or an insulating substrate is used. In this embodiment, since light is incident from the substrate 101 side, a light-transmitting substrate is used. As the substrate 101, for example, various commercially available glass plates such as soda-lime glass, opaque glass, lead glass, strengthened glass, and ceramic glass; a non-alkali glass substrate such as an aluminosilicate glass substrate or a barium borosilicate glass substrate; a quartz substrate; and the like are given.

Next, a photoelectric conversion device illustrated in FIG. 1 is described in detail with respect to specific components thereof and a manufacturing method thereof.

The first electrode 102 is formed over the substrate 101.

There is no particular limitation on the substrate 101 as long as the substrate 101 can withstand a manufacturing process of the photoelectric conversion device of one embodiment of the present invention. A substrate with an insulating surface or an insulating substrate can be used. A glass substrate is preferably used because a large substrate can be used and cost can be reduced. For example, large substrates which are distributed as glass substrates for liquid crystal displays having a size of 300 mm×400 mm called the first generation, 400 mm×500 mm called the second generation, 550 mm×650 mm called the third generation, 730 mm×920 mm called the fourth generation, 1000 mm×1200 mm called the fifth generation, 2450 mm×1850 mm called the sixth generation, 1870 mm×2200 mm called the seventh generation, and 2000 mm×2400 mm called the eighth generation, or the like can be used for the substrate 101.

A film of conductive oxynitride containing zinc and aluminum is formed as the first electrode 102 by a sputtering method or the like. The film of conductive oxynitride is preferably formed to a thickness of about 50 nm to 500 nm. In this embodiment, the thickness of the film of conductive oxynitride is 100 nm.

The film of conductive oxynitride containing zinc and aluminum can be formed in a rare gas atmosphere or an atmosphere containing a rare gas and an oxygen gas by a sputtering method using a target containing zinc oxide and aluminum nitride. Note that the light-transmittance of the film of conductive oxynitride can be improved by forming it in an atmosphere containing a rare gas and an oxygen gas. Note also that forming the conductive oxynitride in such an atmosphere containing an oxygen gas increases the resistivity of the conductive oxynitride. Therefore, the concentration of an oxygen gas is preferably greater than or equal to 0.10%, or more preferably, greater than or equal to 0.36% and less than 5%. In addition, the resistivity of the conductive oxynitride can be reduced by performing a sputtering method in an atmosphere containing only a rare gas such as argon.

Further, a heat treatment may be performed after the conductive oxynitride containing zinc and aluminum is deposited by a sputtering method. The heat treatment is preferably performed in a nitrogen atmosphere. The heat treatment is preferably performed at a temperature greater than or equal to 150° C. and less than or equal to 350° C., or more preferably, greater than or equal to 150° C. and less than or equal to 250° C.

Alternatively, a sputtering method may be performed in a state in which aluminum nitride chips are placed over a target containing zinc oxide. In this case, the aluminum content in the aluminum nitride chip is made larger than the aluminum content in the target containing zinc oxide. In this manner, the amount of nitride and that of aluminum in the conductive oxynitride can be easily adjusted. Note that the aluminum nitride chips are preferably placed so as to have point symmetry to each other. By placing the aluminum nitride chips in this manner, nitride and aluminum can be uniformly contained in the formed conductive oxynitride.

For instance, the conductive oxynitride containing zinc and aluminum can be formed in the following manner: aluminum nitride chips (each in a size of 10 mm×10 mm×1 mm) are placed so as to have point symmetry to each other over a target (ZnO:AlN=100:1 (mol)) with a diameter of 6 inches obtained by sintering zinc oxide and aluminum nitride; and sputtering is performed in an argon atmosphere with the distance between the substrate and the target set to 185 mm, under a pressure of 0.4 Pa, with a radio frequency (RF) power source of 0.5 kW, and at room temperature.

The conductive oxynitride containing zinc and aluminum in this embodiment can be manufactured without indium (In), which is a rare metal. Therefore, the cost of the target can be half to two thirds of that of a light-transmitting conductive film made of a compound of indium oxide and tin oxide (ITO). Accordingly, the manufacturing cost of the photoelectric conversion device 100 can be reduced.

Note that for a sputtering apparatus, a DC power source is preferably used, in which a dust reduction and even thickness distribution can be realized. Note that in the case where sputtering is performed in a state in which the aluminum nitride chips are placed over the target containing zinc oxide, radio frequency (RF) power source is preferably used since aluminum nitride is not conductive.

In the above manner, a light-transmitting conductive film made of the conductive oxynitride containing zinc and aluminum can be formed.

Over the first electrode 102, the first impurity semiconductor layer 112p, the semiconductor layer 114i, and the second impurity semiconductor layer 116n are formed. Here, a manufacturing method in which amorphous silicon layers are used as the first impurity semiconductor layer 112p, the semiconductor layer 114i, and the second impurity semiconductor layer 116n is described as one embodiment; however, the present invention is not limited to this embodiment and any other manufacturing method can be employed as appropriate.

The first impurity semiconductor layer 112p, the semiconductor layer 114i, and the second impurity semiconductor layer 116n are formed using a semiconductor source gas and a dilution gas as a reaction gas by a chemical vapor deposition (CVD) method, typically by a plasma CVD method. As the semiconductor source gas, a silicon hydride typified by silane or disilane, a silicon chloride such as SiH₂Cl₂, SiHCl₃, or SiCl₄, or a silicon fluoride such as SiF₄ can be used. As the dilution gas, hydrogen is typically given. As well as hydrogen, one or more kinds of rare gas elements selected from helium, argon, krypton, and neon can be used as the dilution gas. Further, as the dilution gas, plural kinds of gases (e.g., hydrogen and argon) can be used in combination.

For example, the first impurity semiconductor layer 112p, the semiconductor layer 114i, and the second impurity semiconductor layer 116n can be formed using the above-mentioned reaction gas with a plasma CVD apparatus by applying a high-frequency electric power with a power frequency of greater than or equal to 3 MHz and less than or equal to 300 MHz. Instead of applying the high-frequency electric power, a microwave power with a power frequency of greater than or equal to 1 GHz and less than or equal to 5 GHz, typically 2.45 GHz may be applied. For example, the first impurity semiconductor layer 112p, the semiconductor layer 114i, and the second impurity semiconductor layer 116n can be formed using glow discharge plasma in a treatment chamber of a plasma CVD apparatus with use of a mixture of silicon hydride (typically silane) and hydrogen. Glow discharge plasma is produced by application of high-frequency electric power with a power frequency of greater than or equal to 3 MHz and less than or equal to 30 MHz, typically 13.56 MHz or 27.12 MHz, or high-frequency electric power with a power frequency in the VHF band of 30 MHz to about 300 MHz, typically 60 MHz. The substrate is heated at greater than or equal to 100° C. and less than or equal to 300° C., preferably at greater than or equal to 120° C. and less than or equal to 220° C.

An amorphous silicon layer is formed as the semiconductor layer 114i here. Specifically, the amorphous silicon layer can be formed in the following manner: a reaction gas is introduced into a treatment chamber; and a predetermined pressure is maintained to generate glow discharge plasma. Note that it is preferable that the oxygen concentration and the carbon concentration in the semiconductor layer 114i be as low as possible. Specifically, the oxygen concentration and the carbon concentration in the treatment chamber and the oxygen concentration and the carbon concentration of the reaction gas (purity of the reaction gas) are controlled so that the oxygen concentration and the carbon concentration in the non-single-crystal semiconductor layer 114i are less than 5×10¹⁸/cm³, preferably less than 1×10¹⁸/cm³.

Further, in order to make the oxygen concentration and the carbon concentration in the semiconductor layer 114i as low as possible, the semiconductor layer 114i is preferably formed in an ultra high vacuum (UHV) treatment chamber. Specifically, it is preferable that the semiconductor layer 114i be formed in a treatment chamber in which the degree of vacuum can reach greater than 1×10⁻⁸ Pa and less than or equal to 1×10⁻⁵ Pa.

A doping gas including an impurity imparting one conductivity type is mixed into a reaction gas including a semiconductor source gas and a dilution gas, so that an impurity semiconductor layer having one conductivity type is formed as the first impurity semiconductor layer 112p. In this embodiment, a doping gas including an impurity imparting p-type conductivity is mixed, so that a p-type amorphous silicon layer is formed. As the impurity imparting p-type conductivity, boron or aluminum which is an element belonging to Group 13 in the periodic table and the like are typically given. For example, a doping gas such as diborane is mixed into a reaction gas, whereby a p-type amorphous silicon layer can be formed.

As the second impurity semiconductor layer 116n, an impurity semiconductor layer having a conductivity type opposite to the first impurity semiconductor layer 112p is formed. In this embodiment, a doping gas including an impurity imparting n-type conductivity is mixed into a reaction gas, so that an n-type amorphous silicon layer is formed. As the impurity imparting n-type conductivity, phosphorus, arsenic, or antimony which is an element belonging to Group 15 in the periodic table and the like are typically given. For example, a doping gas such as phosphine is mixed into a reaction gas, whereby an n-type amorphous silicon layer can be formed.

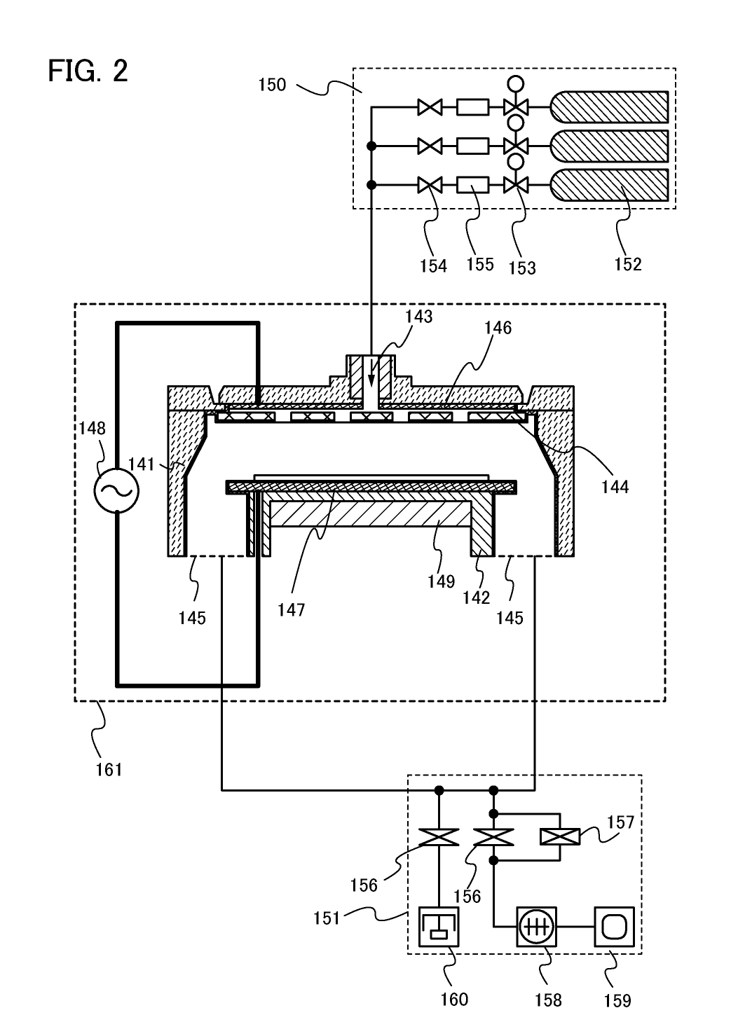

Here, FIG. 2 is a schematic view of a CVD apparatus which can be used for formation of the first impurity semiconductor layer 112p, the semiconductor layer 114i, and the second impurity semiconductor layer 116n.

A plasma CVD apparatus 161 illustrated in FIG. 2 is connected to a gas supply means 150 and an exhaust means 151.

The plasma CVD apparatus 161 includes a treatment chamber 141, a stage 142, a gas supply portion 143, a shower plate 144, an exhaust port 145, an upper electrode 146, a lower electrode 147, an alternate-current power source 148, and a temperature controller 149.

The treatment chamber 141 is formed using a material having rigidity and the inside thereof can be subjected to vacuum exhaust (preferably ultra-high vacuum exhaust). The treatment chamber 141 is provided with the upper electrode 146 and the lower electrode 147. Note that in FIG. 2, a structure of a capacitive coupling type (a parallel plate type) is illustrated; however, another structure such as a structure of an inductive coupling type can be used, as long as plasma can be produced in the treatment chamber 141 by applying two or more different high-frequency electric powers.

Here, in order to form the semiconductor layer 114i of this embodiment, it is preferable to provide an environment in which the oxygen concentration and the carbon concentration in the treatment chamber 141 are as low as possible. Specifically, as the treatment chamber 141, an ultra high vacuum treatment chamber in which the degree of vacuum can reach greater than 1×10⁻⁸ Pa and less than or equal to 1×10⁻⁵ Pa is preferably provided. After the treatment chamber 141 is subjected to vacuum exhaust to a degree of vacuum of greater than 1×10⁻⁸ Pa and less than or equal to 1×10⁻⁵ Pa, a reaction gas is introduced to form the semiconductor layer 114i, whereby the concentrations of oxygen and carbon which are introduced in formation of the semiconductor layer 114i can be low.

When a treatment is performed with the plasma CVD apparatus 161 illustrated in FIG. 2, a given reaction gas is supplied from the gas supply portion 143. The supplied reaction gas is introduced into the treatment chamber 141 through the shower plate 144. High frequency power is applied by the alternate-current power source 148 connected to the upper electrode 146 and the lower electrode 147 to excite the reaction gas in the treatment chamber 141, thereby producing plasma. Further, the reaction gas in the process chamber 141 is exhausted through the exhaust port 145 that is connected to a vacuum pump. Further, with the use of the temperature controller 149, a plasma treatment can be performed while an object is being heated.

The gas supply means 150 includes cylinders 152 each of which is filled with a reaction gas, pressure adjusting valves 153, stop valves 154, mass flow controllers 155, and the like. The treatment chamber 141 includes a shower plate which is processed in a plate-like shape and provided with a plurality of pores, between the upper electrode 146 and the object to be processed. A reaction gas supplied to the upper electrode 146 is supplied to the treatment chamber 141 from these pores through an inner hollow structure.

The exhaust means 151 which is connected to the treatment chamber 141 has a function of vacuum evacuation and a function of controlling the pressure inside the treatment chamber 141 to be maintained at a predetermined pressure when a reaction gas is made to flow. The exhaust means 151 includes in its structure butterfly valves 156, a conductance valve 157, a turbo molecular pump 158, a dry pump 159, and the like. In the case of arranging the butterfly valve 156 and the conductance valve 157 in parallel, the butterfly valve 156 is closed and the conductance valve 157 is operated, so that the evacuation speed of the reaction gas is controlled and thus the pressure in the treatment chamber 141 can be kept in a predetermined range. Moreover, the butterfly valve 156 having higher conductance is opened, so that high-vacuum evacuation can be performed.

In the case of subjecting the treatment chamber 141 to ultra-high vacuum exhaust, a cryopump 160 is preferably used together. Alternatively, when exhaust is performed up to ultra-high vacuum as final vacuum, the inner wall of the treatment chamber 141 may be polished into a mirror surface, and the treatment chamber 141 may be provided with a heater for baking in order to reduce gas emission from the inner wall.

Note that by a precoating treatment performed so that a film is formed covering the entire inner wall of the treatment chamber 141, it is possible to prevent an impurity attached to or included in the inner wall of the treatment chamber from mixing into a film (for example, the semiconductor layer 114i) or the like. For example, in the case of forming a non-single-crystal silicon layer as the semiconductor layer 114i, a film containing silicon as its main component (for example, amorphous silicon) may be formed as a precoating treatment. Note that it is preferable that oxygen and carbon be not contained in the film formed by a precoating treatment.

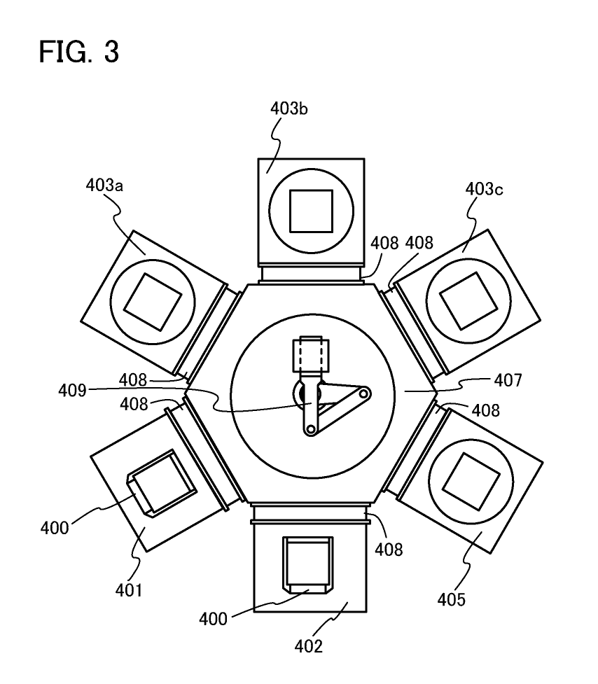

Note that each of the first impurity semiconductor layer 112p, the semiconductor layer 114i, and the second impurity semiconductor layer 116n is doped with the small amount of an impurity for the purpose of controlling valence electron and it is preferable that these layers are successively formed so that the interfaces with each layer are not exposed to the air. Therefore, it is desirable to employ a multi-chamber structure provided with a plurality of film formation treatment chambers. For example, a CVD apparatus illustrated in FIG. 2 may have a multi-chamber structure as illustrated in FIG. 3.

The plasma CVD apparatus illustrated in FIG. 3 includes a load chamber 401, an unload chamber 402, a treatment chamber (1) 403a, a treatment chamber (2) 403b, a treatment chamber (3) 403c, and a spare chamber 405 around a common chamber 407. For example, a p-type semiconductor layer (in this embodiment, the first impurity semiconductor layer 112p) is formed in the treatment chamber (1) 403a, an i-type semiconductor layer (in this embodiment, the semiconductor layer 114i) is formed in the treatment chamber (2) 403b, and an n-type semiconductor layer (in this embodiment, the second impurity semiconductor layer 116n) is formed in the treatment chamber (3) 403c. In the plasma CVD apparatus illustrated in FIG. 3, a treatment chamber (the treatment chamber 141 illustrated in FIG. 2) in which the oxygen concentration and the carbon concentration are made as low as possible is used for at least the treatment chamber (2) 403b in which the semiconductor layer 114i is formed. Of course, it is preferable that the oxygen concentration and the carbon concentration be made as low as possible in the whole plasma CVD apparatus including chambers (a load chamber, an unload chamber, treatment chambers, and a spare chamber).

An object to be processed is transferred to and from each chamber through the common chamber 407. A gate valve 408 is provided between the common chamber 407 and each of the rest of the chambers so that treatments carried out in different chambers may not interfere with each other. The object to be processed (the substrate) is placed in a cassette 400 provided in the load chamber 401 and transferred to each treatment chamber by a transfer means 409 of the common chamber 407. After a desired treatment is terminated, the object to be processed is placed in the cassette 400 provided in the unload chamber 402. In the apparatus with the multi-chamber structure as illustrated in FIG. 3, a treatment chamber can be provided for each kind of films to be formed, and a plurality of different kinds of films can be formed in succession without being exposed to the air.

An example of the formation of the first impurity semiconductor layer 112p, the semiconductor layer 114i, and the second impurity semiconductor layer 116n is described with reference to FIG. 3.

The substrate 101 over which the first electrode 102 is formed is placed as an object to be processed in the cassette 400 of the load chamber 401. By the transfer means 409 of the common chamber 407, the object to be processed is transferred to the treatment chamber (1) 403a. The first impurity semiconductor layer 112p is formed over the first electrode 102 of the object to be processed. Here, a p-type microcrystalline silicon layer is formed as the first impurity semiconductor layer 112p.

By the transfer means 409 of the common chamber 407, the object to be processed is transferred from the treatment chamber (1) 403a to the treatment chamber (2) 403b. The semiconductor layer 114i is formed over the first impurity semiconductor layer 112p of the object to be processed. The treatment chamber (2) 403b is, for example, an ultra-high treatment chamber in which the oxygen concentration and the carbon concentration are made as low as possible.

A reaction gas to be used for formation of the semiconductor layer 114i is introduced into the treatment chamber (2) 403b to form a film. A semiconductor source gas and a dilution gas are used as the reaction gas to be used for formation of the semiconductor layer 114i. The oxygen concentration and the carbon concentration of the reaction gas are made as low as possible.

Here, an example of the formation of the semiconductor layer 114i is given. Silane (SiH₄) with a flow rate of 280 sccm, hydrogen (H₂) with a flow rate of 300 sccm are introduced into the treatment chamber (2) 403b and stabilized. The pressure in the treatment chamber (2) 403b is set to 170 Pa, and the temperature of the object to be processed is set to 280° C. Plasma discharge is performed under the condition where the RF power source frequency is 13.56 MHz and the power of the RF power source is 60 W, whereby a non-single-crystal silicon layer is formed. Further, the environment in the treatment chamber (2) 403b and the purity of the gas to be introduced into the treatment chamber (2) 403b are controlled so that the concentrations of oxygen and carbon which are contained in the semiconductor layer 114i are less than 5×10¹⁸/cm³, preferably less than 1×10¹⁸/cm³.

By the transfer means 409 of the common chamber 407, the object to be processed is transferred from the treatment chamber (2) 403b and the object to be processed is transferred to the treatment chamber (3) 403c, and the second impurity semiconductor layer 116n is formed over the semiconductor layer 114i of the object to be processed. Here, as the second impurity semiconductor layer 116n, an n-type amorphous silicon layer is formed.

By the transfer means 409 of the common chamber 407, the object to be processed is transferred from the treatment chamber (3) 403c and placed in the cassette 400 in the unload chamber 402.

In the above-described manner, the first impurity semiconductor layer 112p, the semiconductor layer 114i, and the second impurity semiconductor layer 116n are formed, whereby the unit cell 110 can be formed.

The second electrode 140 is formed over the second impurity semiconductor layer 116n.

As the second electrode 140, a reflective electrode is formed using aluminum, silver, titanium, tantalum, copper, or the like by a sputtering method or the like. Note that it is preferable to form projections and depressions at the interface between the second electrode 140 and the second impurity semiconductor layer 116n because reflectance is increased.

In the above manner, the photoelectric conversion device 100 in which the photocurrent extraction efficiency is improved can be manufactured at low cost.

Note that the structure and method described in this embodiment can be implemented by being combined as appropriate with the structures and methods described in other embodiments in this specification.

### Embodiment 2

In this embodiment, a photoelectric conversion device having a structure different from the structure described in the above embodiment is described. Specifically, an example in which the number of unit cells to be stacked is different from that in the photoelectric conversion device illustrated in FIG. 1 is described.

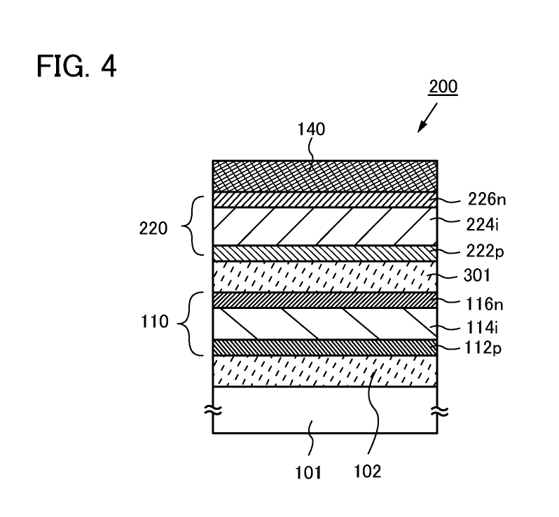

FIG. 4 is a tandem photoelectric conversion device 200 in which two unit cells are stacked. The photoelectric conversion device 200 includes the unit cell 110 formed over the substrate 101 which is provided with the first electrode 102, an intermediate conductive layer 301 formed over the unit cell 110, a unit cell 220 formed over the intermediate conductive layer 301, and the second electrode 140 formed over the unit cell 220.

The unit cell 110 has a structure in which the first impurity semiconductor layer 112p, the semiconductor layer 114i, and the second impurity semiconductor layer 116n are sequentially stacked from the first electrode 102 side.

The unit cell 220 has a structure in which a third impurity semiconductor layer 222p, a semiconductor layer 224i, and a fourth impurity semiconductor layer 226n are sequentially stacked from the unit cell 110 side. The unit cell 220 includes at least one semiconductor junction.

The conductive oxynitride containing zinc and aluminum which is given for the first electrode 102 can be used for the intermediate conductive layer 301.

Alternatively, the intermediate conductive layer can be formed by stacking indium oxide, an indium tin oxide alloy, zinc oxide, titanium oxide, magnesium zinc oxide, cadmium zinc oxide, cadmium oxide, an oxide semiconductor InGaO₃ZnO₅, an In—Ga—Zn—O-based amorphous oxide semiconductor, and the like, in addition to the conductive oxynitride containing zinc and aluminum.

In the photoelectric conversion device 200 which is illustrated in FIG. 4, in the case where light is incident from the substrate 101 side, the semiconductor layer 114i of the unit cell 110 which is nearer to the light incidence side is preferably formed using a semiconductor having a larger band gap than the semiconductor layer 224i of the unit cell 220. Typically, it is preferable that the semiconductor layer 114i of the unit cell 110 be formed using an anamorphous semiconductor (such as amorphous silicon or amorphous silicon germanium) and the semiconductor layer 224i of the unit cell 220 be formed using a microcrystalline semiconductor (such as microcrystalline silicon or microcrystalline silicon germanium), a polycrystalline semiconductor (such as polysilicon or polysilicon germanium) or a single crystal semiconductor (such as single crystal silicon). Alternatively, it is preferable that the semiconductor layer 114i of the unit cell 110 be formed using a microcrystalline semiconductor (such as microcrystalline silicon or microcrystalline silicon germanium) and the semiconductor layer 224i of the unit cell 220 be formed using a polycrystalline semiconductor (such as polysilicon or polysilicon germanium) or a single crystal semiconductor (such as single crystal silicon). Note that a manufacturing method of the semiconductor layer 114i which is described in Embodiment 1 can be used in an appropriate manner as a manufacturing method of the semiconductor layer 224i.

The third impurity semiconductor layer 222p and the fourth impurity semiconductor layer 226n are formed using an amorphous semiconductor (typically amorphous silicon or amorphous silicon carbide), a microcrystalline semiconductor (typically microcrystalline silicon), a polycrystalline semiconductor (polysilicon), or a single crystal semiconductor (single crystal silicon). Further, either the third impurity semiconductor layer 222p or the fourth impurity semiconductor layer 226n is a p-type semiconductor layer, and the other is an n-type semiconductor layer. Furthermore, as the third impurity semiconductor layer 222p, an impurity semiconductor layer having a conductivity type opposite to the second impurity semiconductor layer 116n of the unit cell 110 is formed. As the fourth impurity semiconductor layer 226n, an impurity semiconductor layer having a conductivity type opposite to the third impurity semiconductor layer 222p is formed. For example, a p-type semiconductor layer is formed as the third impurity semiconductor layer 222p, and an n-type semiconductor layer is formed as the fourth impurity semiconductor layer 226n.

Note that it is not necessary to provide the substrate 101 when the semiconductor layer 224i, the third impurity semiconductor layer 222p, and the fourth impurity semiconductor layer 226n of the unit cell 220 are formed using a single crystal semiconductor.

Note that another unit cell may be further stacked, so that a stack type photoelectric conversion device or the like is formed.

Note that the structure described in this embodiment can be implemented by being combined as appropriate with structures described in other embodiments in this specification.

### Embodiment 3

In this embodiment, an example of an integrated photoelectric conversion device (a photoelectric conversion device module) is described in which a plurality of photoelectric conversion cells is formed over one substrate and the plurality of photoelectric conversion cells is connected in series, whereby a photoelectric conversion device is integrated. Further, in this embodiment, an example of the integration of a tandem photoelectric conversion device in which two unit cells are stacked in a longitudinal direction is described. Note that a photoelectric conversion device having one unit cell as illustrated in FIG. 1 may be integrated or a photoelectric conversion device in which three or more unit cells are stacked may be integrated. Hereinafter, a process for manufacturing an integrated photoelectric conversion device and the structure of the integrated photoelectric conversion device are briefly described.

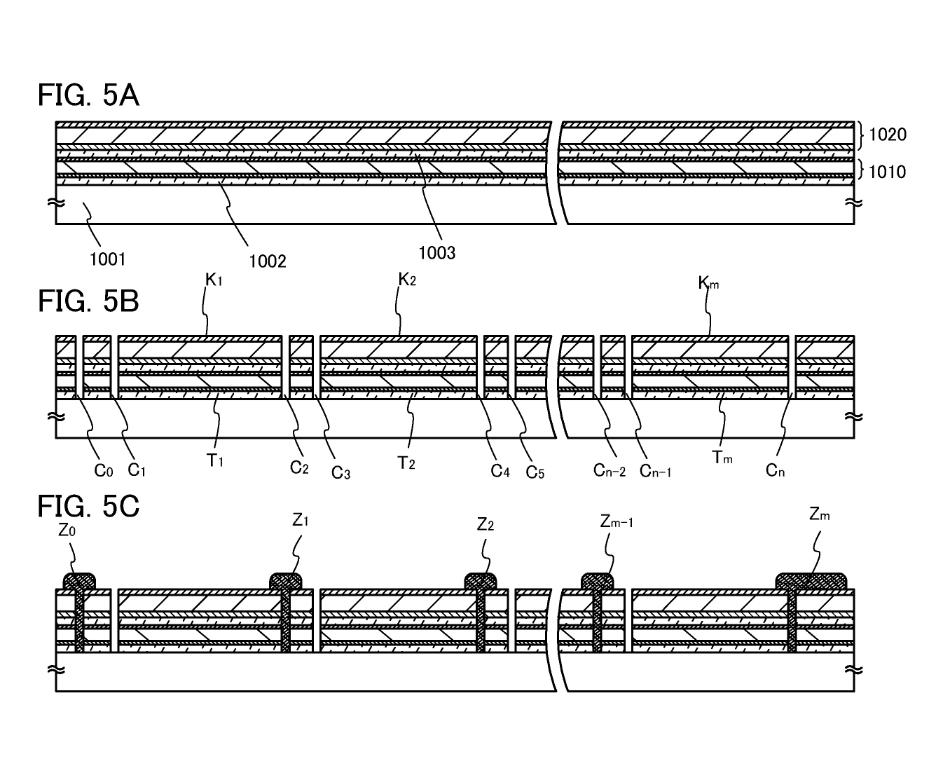

In FIG. 5A, a first electrode 1002 is provided over a substrate 1001. Alternatively, the substrate 1001 provided with the first electrode 1002 is prepared. The first electrode 1002 is formed to a thickness of 40 nm to 200 nm (favorably 50 nm to 100 nm) using the conductive oxynitride containing zinc and aluminum which is given for the first electrode 102 in Embodiment 1 by a sputtering method, an evaporation method, or a printing method.

Over the first electrode 1002, a unit cell 1010, an intermediate conductive layer 1003, and the unit cell 1020 are sequentially stacked. The photoelectric conversion layer included in each of the unit cells 1010 and 1020 is formed using a semiconductor layer manufactured by a plasma CVD method here and includes a semiconductor junction typified by a p-i-n junction. Here, an i-layer of the photoelectric conversion layer which includes the unit cell 1010 placed on the light incidence side is preferably formed using a semiconductor having a larger band gap than an i-layer of a semiconductor layer of the unit cell 1020; therefore, the tandem structure described in Embodiment 2 can be used as appropriate. Further, the intermediate conductive layer 1003 is formed in a manner similar to the intermediate conductive layer 301 which is described in Embodiment 2.

Next, a photoelectric conversion cell which is subjected to element isolation is formed, so that a photoelectric conversion cell is integrated. A method for integrating a photoelectric conversion cell and a method for conducting element isolation are not limited in particular. Here, an example in which photoelectric conversion cells are separated into each cell and adjacent photoelectric conversion cells are electrically connected in series is described.

As illustrated in FIG. 5B, in order to form a plurality of photoelectric conversion cells over one substrate, openings C₀ to Cₙ which penetrate through a stack including the unit cell 1010, the intermediate conductive layer 1003, and the unit cell 1020 and the first electrode 1002 are formed by a laser processing method. The openings C₀, C₂, C₄, . . . , Cₙ₋₂, and Cₙ are openings for insulating and separating unit cells, and provided to form a plurality of photoelectric conversion cells which are subjected to element isolation. Further, the openings C₁, C₃, C₅, . . . , and Cₙ₋₁ are provided to form connections between separated first electrodes and second electrodes to be formed later over the stack including the unit cell 1010, the intermediate conductive layer 1003, and the unit cell 1020. By formation of the openings C₀ to Cₙ, the first electrode 1002 is divided into first electrodes T₁ to Tₘ, and the stack including the unit cell 1010, the intermediate conductive layer 1003, and the unit cell 1020 is divided into multijunction cells K₁ to Kₘ. The kind of lasers used in a laser processing method for forming the openings is not limited, but a Nd-YAG laser, an excimer laser, or the like is preferably used. In any case, by performing laser processing in a state where the first electrode 1002, the unit cell 1010, the intermediate conductive layer 1003, and the unit cell 1020 are stacked, the first electrode 1002 can be prevented from being separated from the substrate 1001 during processing.

As illustrated in FIG. 5C, insulating layers Z₀ to Zₘ with which the openings C₀, C₂, C₄, . . . Cₙ₋₂, and Cₙ are filled and which cover upper end portions of the openings C₀, C₂, C₄, . . . Cₙ₋₂, and Cₙ are formed. The insulating layers Z₀ to Zₘ can be formed by a screen printing method using a resin material having an insulating property such as an acrylic resin, a phenol resin, an epoxy resin, or a polyimide resin. For example, insulating resin patterns are formed using a resin composition in which cyclohexane, isophorone, high resistance carbon black, aerosil (registered trademark), dispersant, a defoaming agent, and a leveling agent are mixed with a phenoxy resin by a screen printing method so that the openings C₀, C₂, C₄, . . . , Cₙ₋₂, and Cₙ are filled therewith. After the insulating resin patterns are formed, thermal hardening is performed in an oven at 160° C. for 20 minutes, whereby the insulating layers Z₀ to Zₘ can be formed.

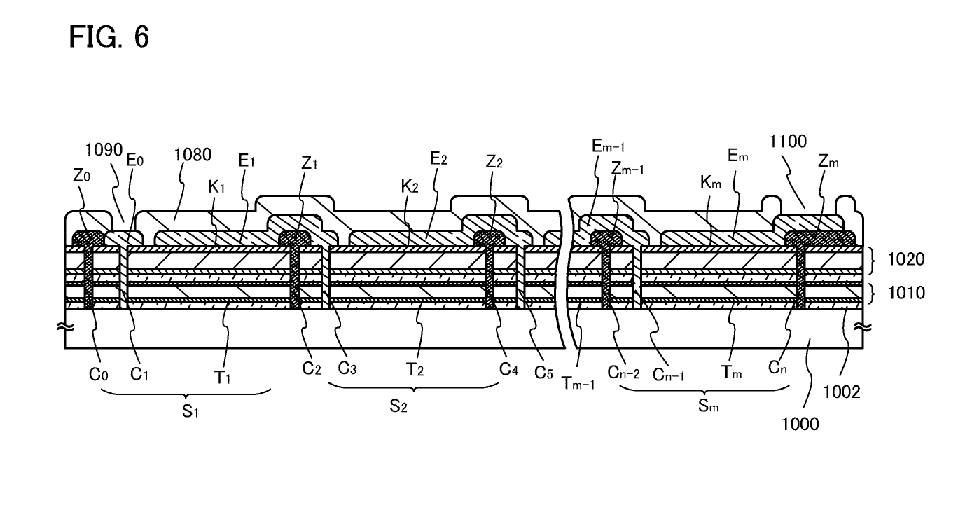

Next, second electrodes E₀ to Eₘ illustrated in FIG. 6 are formed. The second electrodes E₀ to Eₘ are formed using a conductive material. The second electrodes E₀ to Eₘ may be formed by a sputtering method or a vacuum evaporation method using a conductive layer which includes aluminum, silver, molybdenum, titanium, chromium, or the like. Alternatively, the second electrodes E₀ to Eₘ can be formed using a conductive material which can be discharged. In the case where the second electrodes E₀ to Eₘ are formed using a conductive material which can be discharged, predetermined patterns are directly formed by a screen printing method, an ink-jet method, a dispenser method, or the like. For example, the second electrodes E₀ to Eₘ can be formed using a conductive material containing conductive particles of metal such as Ag, Au, Cu, W, or Al as its main component. In the case of manufacturing a photoelectric conversion device using a large-area substrate, the resistance of each of the second electrodes E₀ to Eₘ is preferably low. Therefore, a conductive material may be used in which particles of any of gold, silver, and copper which have low resistivity, preferably silver or copper which has low resistance are dissolved or dispersed as particles of metal in a solvent. Further, in order to sufficiently fill the openings C₁, C₃, C₅, . . . , Cₙ₋₁ which are formed by laser processing with a conductive material, nanopaste with an average grain size of conductive particles of 5 nm to 10 nm is preferably used.

The second electrodes E₀ to Eₘ may be formed by discharging a conductive composition containing conductive particles in each of which a conductive material is covered with another conductive material. For example, as a conductive particle formed of Cu whose periphery is covered with Ag, a conductive particle provided with a buffer layer which includes nickel or nickel boron between Cu and Ag may be used. As the solvent, esters such as butyl acetate, alcohols such as isopropyl alcohol, or an organic solvent such as acetone is used. The surface tension and viscosity of the conductive composition which is discharged are appropriately adjusted by controlling the concentration of a solution and adding a surface active agent or the like.

After the conductive composition which forms the second electrodes E₀ to Eₘ is discharged, a drying step and/or a baking step are/is performed under a normal pressure or a reduced pressure by laser beam irradiation, rapid thermal annealing (RTA), heating using a heating furnace, or the like. Both of the drying and baking steps are a heat treatment, but for example, the drying step is performed at 100° C. for three minutes and the baking step is performed at 200° C. to 350° C. for 15 minutes to 120 minutes. Through this process, fusion and welding are accelerated due to curing and shrinking a peripheral resin by the solvent in the conductive composition is volatilized or the dispersant in the conductive composition is chemically removed. The drying and baking are performed in an oxygen atmosphere or a nitrogen atmosphere, or in the air atmosphere. However, it is preferable that the drying and baking be performed under an oxygen atmosphere in which a solvent in which conductive particles are dissolved or dispersed is easily removed.

The second electrodes E₀ to Eₘ are in contact with the unit cell 1020 which is the topmost layer of the multijunction cells K₁ to Kₘ. The contact between the second electrodes E₀ to Eₘ and the unit cell 1020 is ohmic contact, whereby low contact resistance can be obtained.

The second electrodes E₀ to Eₘ₋₁ are formed to be connected to the first electrodes T₁ to Tₘ, respectively, in the openings C₁, C₃, C₅, . . . , Cₙ₋₁. That is, the openings C₁, C₃, C₅, . . . , Cₙ₋₁ are filled with the same material as the second electrodes E₀ to Eₘ₋₁. In such a manner, for example, the second electrode E₁ can be electrically connected to the first electrode T₂ and the second electrode Eₘ₋₁ can be electrically connected to the first electrode Tₘ. In other words, the second electrodes can be electrically connected to the first electrodes adjacent thereto, and each of the multijunction cells K₁ to Kₘ can obtain electrical connection in series.

Thus, over the substrate 1001, a photoelectric conversion cell S₁ including the first electrode T₁, the multijunction cell K₁, and the second electrode E₁, . . . , and a photoelectric conversion cell Sₘ including the first electrode Tₘ, the multijunction cell Kₘ, and the second electrode Eₘ are formed. The m photoelectric conversion cells S₁ to Sₘ are electrically connected in series.

A sealing resin layer 1080 is formed so as to cover the photoelectric conversion cells S₁ to Sₘ. The sealing resin layer 1080 may be formed using an epoxy resin, an acrylic resin, or a silicone resin. Further, an opening 1090 is formed in the sealing resin layer 1080 over the second electrode E₀, and an opening 1100 is formed in the sealing resin layer 1080 over the second electrode Eₘ, so that connection with external wiring can be made in the opening 1090 and the opening 1100. The second electrode E₀ is connected to the first electrode T₁ and serves as one extraction electrode of the photoelectric conversion cells S₁ to Sₘ connected in series. The second electrode Eₘ serves as the other extraction electrode.

An integrated photoelectric conversion device can be manufactured using a photoelectric conversion cell having a non-single-crystal semiconductor layer to which one embodiment of the present invention is applied. By employing an integrated photoelectric conversion device, desired power (current, voltage) can be obtained.

Note that the structure and method described in this embodiment can be implemented by being combined as appropriate with structures and methods described in other embodiments in this specification.

This application is based on Japanese Patent Application serial No. 2009-136740 filed with Japan Patent Office on Jun. 5, 2009, the entire contents of which are hereby incorporated by reference.

What is claimed is:

1. A photoelectric conversion device comprising:
at least one unit cell between a first electrode and a second electrode in which a first impurity semiconductor layer having one conductivity type, a semiconductor layer, and a second impurity semiconductor layer having a conductivity type opposite to the first impurity semiconductor layer are sequentially stacked to form a semiconductor junction,
wherein the first electrode or the second electrode includes conductive oxynitride containing zinc and aluminum.

2. The photoelectric conversion device according to claim 1,
wherein a relative proportion of the zinc is less than or equal to 47 at. %.

3. The photoelectric conversion device according to claim 1,
wherein a relative proportion of the zinc is higher than a relative proportion of the aluminum.

4. The photoelectric conversion device according to claim 1,
wherein the relative proportion of the aluminum is higher than a relative proportion of nitrogen.

5. The photoelectric conversion device according to claim 1,
wherein a nitrogen concentration measured by secondary ion mass spectrometry is greater than or equal to 5.0×10²⁰ atoms/cm³ in the conductive oxynitride containing zinc and aluminum.

6. The photoelectric conversion device according to claim 1,
wherein the aluminum is included at 1.0 at. % to 8.0 at. % in the conductive oxynitride containing zinc and aluminum.

7. The photoelectric conversion device according to claim 1,
wherein nitrogen is included at 0.5 at. % to 4.0 at. % in the conductive oxynitride containing zinc and aluminum.

8. A photoelectric conversion device comprising:
a first electrode;
a first unit cell formed over the first electrode;
an intermediate conductive layer formed over the first unit cell;
a second unit cell formed over the intermediate conductive layer; and
a second electrode formed over the second unit cell,
wherein a first impurity semiconductor layer having one conductivity type, a first semiconductor layer, and a second impurity semiconductor layer having a conductivity type opposite to the conductivity type of the first impurity semiconductor layer are sequentially stacked to form a semiconductor junction in the first unit cell,
wherein a third impurity semiconductor layer having one conductivity type, a second semiconductor layer, and a fourth impurity semiconductor layer having a conductivity type opposite to the conductivity type of the third impurity semiconductor layer are sequentially stacked to form a semiconductor junction in the second unit cell, and
wherein the first electrode, the second electrode, or the intermediate conductive layer includes conductive oxynitride containing zinc and aluminum.

9. The photoelectric conversion device according to claim 8,
wherein a relative proportion of the zinc is less than or equal to 47 at. %.

10. The photoelectric conversion device according to claim 8,
wherein a relative proportion of the zinc is higher than a relative proportion of the aluminum.

11. The photoelectric conversion device according to claim 8,
wherein the relative proportion of the aluminum is higher than a relative proportion of nitrogen.

12. The photoelectric conversion device according to claim 8,
wherein a nitrogen concentration measured by secondary ion mass spectrometry is greater than or equal to 5.0×10²⁰ atoms/cm³ in the conductive oxynitride containing zinc and aluminum.

13. The photoelectric conversion device according to claim 8,
wherein the aluminum is included at 1.0 at. % to 8.0 at. % in the conductive oxynitride containing zinc and aluminum.

14. The photoelectric conversion device according to claim 8,
wherein nitrogen is included at 0.5 at. % to 4.0 at. % in the conductive oxynitride containing zinc and aluminum.
